(19) United States
(12) Patent Application Publication
(10) Pub. No.: US 2026/0271507 A1
(43) Pub. Date: Sep. 10, 2026

(54) LIGHT-EMITTING ELEMENT

(71) Applicant: Sharp Display Technology Corporation, Kameyama City, Mie (JP)

(72) Inventor: SHINICHI HANDA, Sakai City, Osaka (JP)

(21) Appl. No.: 19/114,887

(22) PCT Filed: Sep. 29, 2022
(86) PCT No.: PCT/JP2022/036520

§ 371 Date: Mar. 25, 2025

(51) Int. Cl. H10K 50/16; H10K 50/115; H10K 50/15

(52) U.S. Cl. CPC H10K 50/166; H10K 50/115; H10K 50/156

(57) ABSTRACT

A light-emitting element includes: an anode and a cathode; a light-emitting layer positioned between the anode and the cathode, the light-emitting layer including a plurality of quantum dots and an inorganic matrix material with which spaces between the plurality of quantum dots are filled; and at least either (i) an electron transport layer positioned between the light-emitting layer and the cathode and a first auxiliary layer being in contact with the light-emitting layer on a cathode side, the first auxiliary layer being made of a material different from the inorganic matrix material or (ii) a hole transport layer positioned between the anode and the light-emitting layer and a second auxiliary layer being in contact with the light-emitting layer on an anode side, the second auxiliary layer being made of a material different from the inorganic matrix material.

### TECHNICAL FIELD

The disclosure relates to a light-emitting element including quantum dots as a light-emitting material, a display device including a plurality of the light-emitting elements, and a method for manufacturing the light-emitting element.

### BACKGROUND ART

PTL 1 discloses a light-emitting element including a semiconductor nanoparticle layer between electrodes.

### CITATION LIST

### Patent Literature

PTL 1: JP 2007-95685 A

### SUMMARY

### Technical Problem

In a light-emitting element including a light-emitting layer including quantum dots as a light-emitting material, a process that does not contribute to light emission of the quantum dots, such as a quenching process in which energy of excitons generated in the quantum dots moves to another layer, may occur.

### Solution to Problem

According to an embodiment of the disclosure, there is provided a light-emitting element including an anode and a cathode, a light-emitting layer positioned between the anode and the cathode, the light-emitting layer including a plurality of quantum dots and an inorganic matrix material with which spaces between the plurality of quantum dots are filled, a hole transport layer positioned between the anode and the light-emitting layer, an electron transport layer positioned between the light-emitting layer and the cathode, and at least one of a first auxiliary layer being in contact with the light-emitting layer on a cathode side, the first auxiliary layer being made of a material different from the inorganic matrix material, and a second auxiliary layer being in contact with the light-emitting layer on an anode side, the second auxiliary layer being made of a material different from the inorganic matrix material.

According to an embodiment of the disclosure, there is provided a method for manufacturing a light-emitting element including applying a solution including a plurality of quantum dots and a first precursor of a first metal sulfide, then modifying the first precursor into the first metal sulfide, and thus forming a light-emitting layer, and applying a second precursor of a second metal sulfide different from the first metal sulfide, then modifying the second precursor into the second metal sulfide, and thus forming an auxiliary layer being in contact with the light-emitting layer.

### Advantageous Effects of Disclosure

The luminous efficiency of a light-emitting element is improved by improving the probability of occurrence of a process contributing to light emission of a light-emitting layer.

### BRIEF DESCRIPTION OF DRAWINGS

FIG. 1 is a schematic side cross-sectional view of a display device according to a first embodiment, and a schematic view illustrating an inorganic matrix material with which spaces between quantum dots are filled.

FIG. 2 is a schematic plan view of the display device according to the first embodiment.

FIG. 3 is a band diagram illustrating an example of band gaps of respective portions in the light-emitting element according to the first embodiment.

FIG. 4 is a flowchart illustrating an example of a method for manufacturing the display device according to the first embodiment.

FIG. 5 is a schematic side cross-sectional view of a display device according to a second embodiment.

FIG. 6 is a band diagram illustrating an example of band gaps of respective portions in a light-emitting element according to the second embodiment.

FIG. 7 is a band diagram illustrating another example of band gaps of respective portions in the light-emitting element according to the second embodiment.

FIG. 8 is a schematic side cross-sectional view of a display device according to a third embodiment.

### DESCRIPTION OF EMBODIMENTS

### First Embodiment

### Outline of Display Device

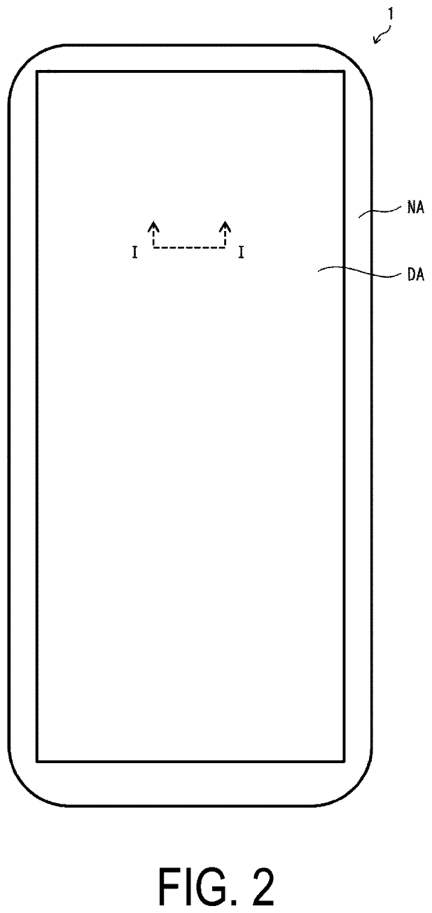

FIG. 2 is a schematic plan view of a display device 1 according to the present embodiment. The display device 1 includes a display portion DA and a frame portion NA formed at an outer periphery of the display portion DA. The display device 1 performs display in the display portion DA by controlling light emission from each of a plurality of light-emitting elements, which will be described later, formed in the display portion DA. In the frame portion NA, a driver or the like for driving each of the plurality of light-emitting elements of the display portion DA may be formed.

### Outline of Substrate and Light-Emitting Element

The display portion DA of the display device 1 according to the present embodiment includes a plurality of red subpixels, a plurality of green subpixels, and a plurality of blue subpixels. The red subpixel is formed with a red light-emitting element, the green subpixel is formed with a green light-emitting element, and the blue subpixel is formed with a blue light-emitting element. The red light-emitting element, the green light-emitting element, and the blue light-emitting element respectively emit red light, green light, and blue light. Thus, the display device 1 performs color display by individually controlling the plurality of light-emitting elements in the display portion DA by a driver or the like formed in the frame portion NA, for example.

Note that in the present embodiment, the “blue light” refers to, for example, light having a light emission central wavelength in a wavelength band equal to or more than 380 nm and equal to or less than 500 nm. The green light refers to, for example, light having a light emission central wavelength in a wavelength band larger than 500 nm and equal to or less than 600 nm. Furthermore, the red light is light having a light emission central wavelength in a wavelength band larger than 600 nm and equal to or less than 780 nm.

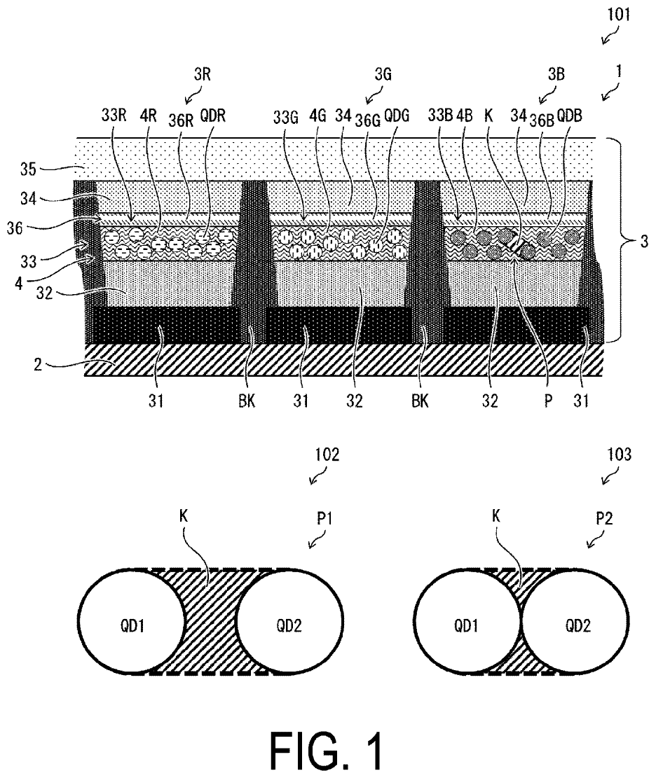

A structure of the display portion DA in the display device 1 according to the present embodiment will be described in more detail with reference to FIG. 1. FIG. 1 is a schematic side cross-sectional view 101 of the display device 1 according to the present embodiment, and a schematic view 102 and a schematic view 103 for illustrating an inorganic matrix material with which spaces between quantum dots are filled, which will be described later.

The schematic side cross-sectional view 101 of the display device 1 illustrated in FIG. 1 is a cross-sectional view taken along a line I-I with arrows illustrated in FIG. 2, and particularly illustrates a side cross-sectional view along a plane being perpendicular to an upper face of the display portion DA and passing through a red light-emitting element 3R, a green light-emitting element 3G, and a blue light-emitting element 3B, which will be described later. Hereinafter, in this specification, all schematic side cross-sectional views of the display device illustrate cross sections at the same position as the cross section illustrated in the schematic side cross-sectional view 101 of FIG. 1.

The schematic view 102 and the schematic view 103 of FIG. 1 are diagrams illustrating two examples of a pair P of two blue quantum dots QDB and a region (space) K therebetween illustrated in the schematic side cross-sectional view 101. In particular, the schematic view 102 and the schematic view 103 are diagrams respectively illustrating a pair P1 and a pair P2, which are examples of the pair of the quantum dot QD1 and the quantum dot QD2.

The display device 1 includes a substrate 2 such as a glass substrate or a film substrate and a light-emitting element 3 on the substrate 2 in the display portion DA. The light-emitting element 3 includes an anode 31, a hole transport layer 32, a light-emitting layer 33, an electron transport layer 34, and a cathode 35 in this order from the substrate 2 side toward the upper face side of the display portion DA. In addition, the light-emitting element 3 according to the present embodiment includes a first auxiliary layer 36 between the light-emitting layer 33 and the electron transport layer 34.

The light-emitting element 3 forms the red light-emitting element 3R including the anode 31, the hole transport layer 32, a red light-emitting layer 33R, the electron transport layer 34, the cathode 35, and the first auxiliary layer 36, which overlap with the red subpixel in a plan view of the substrate 2. Further, the light-emitting element 3 forms the green light-emitting element 3G including the anode 31, the hole transport layer 32, a green light-emitting layer 33G, the electron transport layer 34, the cathode 35, and the first auxiliary layer 36, which overlap with the green subpixel in a plan view of the substrate 2. Further, the light-emitting element 3 forms the blue light-emitting element 3B including the anode 31, the hole transport layer 32, a blue light-emitting layer 33B, the electron transport layer 34, the cathode 35, and the first auxiliary layer 36, which overlap with the blue subpixel in a plan view of the substrate 2.

The display device 1 further includes a bank BK. The bank BK partitions the plurality of light-emitting elements included in the display device 1. The bank BK is formed on the substrate 2, in particular, formed between a plurality of anodes 31 in a plan view of the substrate 2. In the present embodiment, the bank BK partitions the hole transport layer 32, the light-emitting layer 33, the electron transport layer 34, and the first auxiliary layer 36 for each subpixel. Note that the cathode 35 is commonly formed for a plurality of subpixels.

The bank BK may be formed at a position overlapping with an end portion of each anode 31 in a plan view of the substrate 2. In this case, the bank BK can reduce the influence of electric field concentration at the end portion of the anode 31 in each light-emitting element on the injection of holes from the anode 31 to the light-emitting layer 33.

The anode 31 and the cathode 35 are electrodes each of which contains a conductive material and are electrically connected to the hole transport layer 32 and the electron transport layer 34, respectively. When a voltage is applied to at least one of the anode 31 and the cathode 35, holes and electrons are injected from the anode 31 and the cathode 35 into the hole transport layer 32 and the electron transport layer 34, respectively.

In the present embodiment, each of the anodes 31 may be electrically connected to a pixel circuit (not illustrated) formed for each subpixel on the substrate 2. The display device 1 may control the voltage applied to each of the anodes 31 by individually driving the pixel circuits. For example, the display device 1 may control light emission from each light-emitting element by driving the voltage applied to each of the anodes 31 while applying a predetermined voltage to the cathode 35.

At least one of the anode 31 and the cathode 35 is a transparent electrode that transmits visible light. As the transparent electrode, for example, ITO, InZnO, SnO₂, FTO, or the like may be used. Additionally, one of the anode 31 or the cathode 35 may be a reflective electrode. The reflective electrode may contain a metal material having a high reflectivity of visible light, and the metal material may be, for example, Al, Ag, Cu, or Au alone or an alloy thereof.

The hole transport layer 32 is a layer that transports holes injected from the anode 31 to the light-emitting layer 33. As the material of the hole transport layer 32, an organic or inorganic material employed and having hole transport properties in a light-emitting element containing quantum dots, or the like can be used in the related art. The electron transport layer 34 is a layer that transports the electrons injected from the cathode 35 to the light-emitting layer 33. As the material of the electron transport layer 34, an organic or inorganic material employed and having electron transport properties in a light-emitting element containing quantum dots, or the like can be used in the related art.

### Quantum Dot

The light-emitting layer 33 includes the red light-emitting layer 33R, the green light-emitting layer 33G, and the blue light-emitting layer 33B. The red light-emitting layer 33R, the green light-emitting layer 33G, and the blue light-emitting layer 33B are formed at positions overlapping with the red subpixel, the green subpixel, and the blue subpixel, respectively, when the substrate 2 is seen in a plan view.

The red light-emitting layer 33R, the green light-emitting layer 33G, and the blue light-emitting layer 33B include, as quantum dots, a plurality of red quantum dots QDR, a plurality of green quantum dots QDG, and a plurality of blue quantum dots QDB, respectively. When each light-emitting element is driven, holes are injected into each quantum dot from the anode 31 through the hole transport layer 32, and electrons are injected into each quantum dot from the cathode 35 through the electron transport layer 34.

Each of the red quantum dot QDR, the green quantum dot QDG, and the blue quantum dot QDB may have, for example, a so-called core/shell structure including a core and a shell at least partially positioned around the core. In this case, the holes from the anode 31 and the electrons from the cathode 35 are injected into the core of each quantum dot, and light is emitted by excitons generated by recombination of the holes and the electrons. The red quantum dot QDR, the green quantum dot QDG, and the blue quantum dot QDB emit red light, green light, and blue light from the respective cores thereof, respectively.

Note that in the present specification, a “quantum dot” included in the light-emitting layer 33 is a dot having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-like three-dimensional shape, a branch-like three-dimensional shape, or a three-dimensional shape having unevenness on the surface, or a combination thereof.

The quantum dot typically may be composed of a semiconductor. The semiconductor may have a constant band gap. The semiconductor may be a material capable of emitting light and may include at least a material which will be described below. The semiconductor may emit each of red light, green light, and blue light. The semiconductor includes, for example, at least one kind selected from the group consisting of a group II-VI compound, a group III-V compound, and a chalcogenide and a perovskite compound. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include, for example, at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include, for example, at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of elements by using Roman numerals is numbering based on the old International Union of Pure and Applied Chemistry (IUPAC) system or old Chemical Abstracts Service (CAS) system, and the numbering of groups of elements by using Arabic numerals is numbering based on the current IUPAC system.

### Inorganic Matrix Material

Furthermore, each of the red light-emitting layer 33R, the green light-emitting layer 33G, and the blue light-emitting layer 33B includes an inorganic matrix material 4 that fills spaces between the plurality of quantum dots. The inorganic matrix material 4 includes, for example, an inorganic matrix material 4R, an inorganic matrix material 4G, and an inorganic matrix material 4B, which are formed at positions overlapping with the red subpixel, the green subpixel, and the blue subpixel, respectively, in a plan view of the substrate 2. The inorganic matrix material 4R, the inorganic matrix material 4G, and the inorganic matrix material 4B may contain materials different from each other or may contain the same material as each other.

Note that the fact that the inorganic matrix material 4 fills the spaces between the plurality of quantum dots means that the inorganic matrix material 4 fills the region K between the quantum dot QD1 and the quantum dot QD2 as illustrated in the schematic view 102 of the pair P1 illustrated in FIG. 1. In a cross section of the light-emitting layer 33, the region K is a region surrounded by two straight lines (external common tangents) being in contact with outer peripheries of the quantum dot QD1 and the quantum dot QD2 and outer peripheries of the quantum dot QD1 and the quantum dot QD2 facing each other. Thus, as illustrated in the schematic view 103 of the pair P2 illustrated in FIG. 1, even when the quantum dot QD1 and the quantum dot QD2 are close to each other, the region K can exist, and the inorganic matrix material 4 fills the region K.

In addition, the expression “the inorganic matrix material 4 fills the spaces between the plurality of quantum dots” does not necessarily mean that the region K between the quantum dot QD1 and the quantum dot QD2 is entirely made of only the inorganic matrix material 4. For example, a material such as an organic material different from the inorganic matrix material 4 may be contained in the region K between the quantum dot QD1 and the quantum dot QD2. Specifically, for example, the light-emitting layer 33 may include organic ligands that are added to improve the dispersibility of quantum dots in a solution to be used for application and formation and that are coordinated to the outer peripheral surfaces of the quantum dots in the solution. In this case, in the light-emitting layer 33, a weight percentage of the organic ligands to a total weight including the region K may be less than 5%, for example, from the viewpoint of improving the reliability of the light-emitting layer 33.

The inorganic matrix material 4 may fill a region other than the plurality of quantum dots in the light-emitting layer 33. For example, outer edges (an upper face and a lower face) of the light-emitting layer 33 may be covered with the inorganic matrix material 4. Alternatively, due to a portion of the inorganic matrix material 4 positioned from the outer edges of the light-emitting layer 33, the quantum dots may be positioned away from the outer edges. The outer edges of the light-emitting layer 33 need not be formed only by the inorganic matrix material 4, and a part of the quantum dot may be exposed from the inorganic matrix material 4. The inorganic matrix material 4 may be indicated as a portion of the light-emitting layer 33 excluding the plurality of quantum dots.

The inorganic matrix material 4 may include the plurality of quantum dots. The inorganic matrix material 4 may be formed so as to fill the spaces formed between the plurality of quantum dots. The plurality of quantum dots may be embedded in the inorganic matrix material 4 at intervals. The inorganic matrix material 4 may partially or completely fill the spaces between the plurality of quantum dots.

The inorganic matrix material 4 may include a continuous film having an area equal to or larger than 1000 nm² along a plane direction orthogonal to a film thickness direction. The continuous film may be a film that is not separated by a material other than a material constituting the continuous film in one plane. The continuous film may be in the form of an integrated film connected without interruption by chemical bonding of the inorganic matrix material 4.

The inorganic matrix material 4 may be the same material as that of the shell included in each of the plurality of quantum dots. In this case, an average distance between cores adjacent to each other (core-to-core distance) may be equal to or larger than 3 nm in the light-emitting layer 33. Alternatively, the average distance between cores adjacent to each other may be 0.5 times or more an average core diameter. The core-to-core distance is an average of distances between 20 cores adjacent to each other in a space including 20 cores. The core-to-core distance may be kept wider than the distance when the shells are in contact with each other. The average core diameter is obtained by averaging the core diameters of 20 cores in the cross-sectional observation in a space including the 20 cores. The core diameter can be the diameter of a circle having the same area as the core area in the cross-sectional observation.

A concentration of the inorganic matrix material 4 in the light-emitting layer 33 is, for example, an area percentage occupied by the inorganic matrix material 4 in the cross section of the light-emitting layer 33. This concentration may be 10% or more and 90% or less, or 30% or more and 70% or less in the cross-sectional observation. The concentration may be measured, for example, from an area percentage of an image obtained by the cross-sectional observation. When the quantum dots have a core-shell structure, the concentration of the shells may be equal to or more than 1% and equal to or less than 50%. A ratio of the cores and the shells of the quantum dots, and the inorganic matrix material 4 may be adjusted such that a total thereof is equal to or less than 100% as appropriate. As described above, when the shell and the inorganic matrix material 4 cannot be distinguished from each other, the shell may be regarded as a part of the inorganic matrix material 4.

The light-emitting layer 33 may be constituted by the plurality of quantum dots and the inorganic matrix material 4. An intensity of carbon detected by a chain structure when the light-emitting layer 33 is analyzed may be equal to or less than a noise level.

A constituent material of the inorganic matrix material 4 may have a band gap wider than that of the constituent material including the core material of the quantum dots from the viewpoint of reducing the outflow of the holes and the electrons injected into the light-emitting layer 33 to the outside of the light-emitting layer 33 or the penetration of the wave function in a quantum confinement effect. In particular, from the above viewpoint, the constituent material of the inorganic matrix material 4 may have a lower electron affinity and a higher ionization potential than those of the constituent material of the quantum dots.

As the constituent material of the inorganic matrix material 4, a semiconductor or an insulator can be used. For example, the inorganic matrix material 4 may be made of an inorganic semiconductor material. Examples of the constituent material of the inorganic matrix material 4 include, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

Regarding the structure of the inorganic matrix material 4, the configuration described above need not be observed over the entire region of the light-emitting layer 33 as long as the configuration described above is obtained by observing the cross section of the light-emitting layer 33 within a range of about 100 nm in the cross-sectional observation of the light-emitting layer 33. The inorganic matrix material 4 may contain a substance different from the main material that is, for example, an inorganic substance such as an inorganic semiconductor, for example, as an additive.

### First Auxiliary Layer

In each light-emitting element, the first auxiliary layer 36 is positioned between the light-emitting layer 33 and the cathode 35 and, in particular, is in contact with the light-emitting layer 33 on a cathode 35 side. The first auxiliary layer 36 may be made of the same material as the inorganic matrix material but is desirably made of a material different from the inorganic matrix material. The first auxiliary layer 36 includes, for example, a first auxiliary layer 36R, a first auxiliary layer 36G, and a first auxiliary layer 36B that are formed at positions overlapping with the red subpixel, the green subpixel, and the blue subpixel, respectively, in a plan view of the substrate 2. The first auxiliary layer 36R, the first auxiliary layer 36G, and the first auxiliary layer 36B may contain materials different from each other or may contain the same material as each other.

In each light-emitting element according to the present embodiment, a distance between the light-emitting layer 33 and the electron transport layer 34 is increased by a film thickness of the first auxiliary layer 36, in other words, a distance between the quantum dots and the electron transport layer 34 is increased. Thus, in each light-emitting element, for example, the probability of occurrence of a process that does not contribute to light emission of the quantum dots of the light-emitting layer 33 and that includes a quenching process in which the energy of excitons generated in the quantum dots of the light-emitting layer 33 is transferred to the material of the electron transport layer 34 is reduced.

In general, the probability of energy transfer between two semiconductor materials is inversely proportional to the square of a distance between the two semiconductor materials. Thus, since the distance between the light-emitting layer 33 and the electron transport layer 34 is increased by the film thickness of the first auxiliary layer 36, the light-emitting element according to the present embodiment more efficiently reduces the probability of occurrence of a process that does not contribute to the light emission of the quantum dots of the light-emitting layer 33.

Thus, each light-emitting element according to the present embodiment includes the first auxiliary layer 36, thereby increasing the probability of the occurrence of the process contributing to the light emission of the light-emitting layer 33 and improving the luminous efficiency of the light-emitting layer 33. In particular, when the inorganic matrix material 4 fills the spaces between the plurality of quantum dots as in the light-emitting layer 33 according to the present embodiment, excitons generated in the quantum dots easily move to another layer through the inorganic matrix material 4. As a result, in each light-emitting element according to the present embodiment, the first auxiliary layer 36 can more efficiently reduce the probability of the occurrence of the process that does not contribute to the light emission of the light-emitting layer 33.

### Band Gaps of Respective Portions of Light-Emitting Element

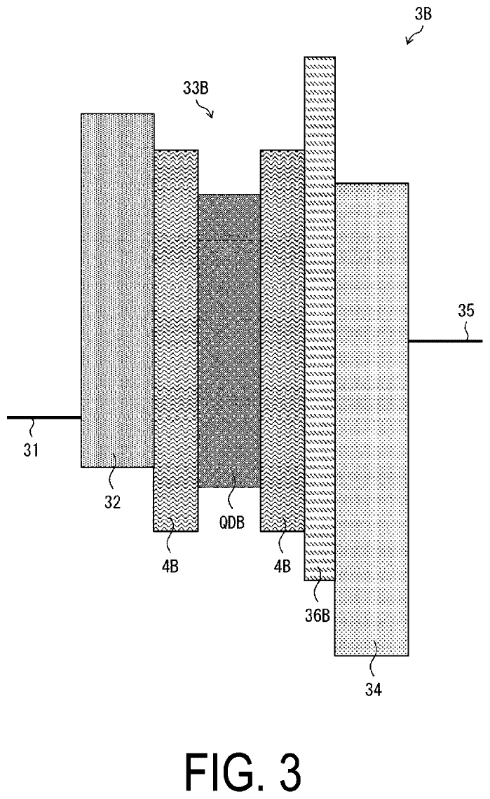

The first auxiliary layer 36 will be described in more detail by describing an example of band gaps of respective portions of the light-emitting element according to the present embodiment. FIG. 3 is a band diagram illustrating an example of the band gaps of the respective portions of the light-emitting element according to the present embodiment, in particular, the blue light-emitting element 3B. Note that each of the band diagrams in this specification has a vacuum level on the upper side in the page. In addition, the left-right direction of each band diagram in this specification represents the thickness direction in the display direction of the display device 1, and the left side of the page is referred to as the anode 31 side and the right side thereof is referred to as the cathode 35 side.

In each band diagram in this specification, respective Fermi levels of the anode 31 and the cathode 35 are illustrated. In addition, the band gaps of the hole transport layer 32, the blue light-emitting layer 33B, the electron transport layer 34, and the first auxiliary layer 36B are also illustrated. In particular, as for the blue light-emitting layer 33B, respective band gaps of the blue quantum dots QDB and the inorganic matrix material 4B are illustrated. In this case, as illustrated in FIG. 3, the band diagram of the blue light-emitting layer 33B is simplified such that the band gaps of the inorganic matrix material 4B are positioned corresponding to both ends of the band gap of the blue quantum dot QDB.

As illustrated in FIG. 3, the first auxiliary layer 36B has a smaller electron affinity than that of the inorganic matrix material 4B. In general, an electron injection barrier from a first layer to a second layer corresponds to energy obtained by subtracting an electron affinity of the second layer from an electron affinity of the first layer. Thus, an electron injection barrier from the electron transport layer 34 to the first auxiliary layer 36B is larger than an electron injection barrier from the electron transport layer 34 to the inorganic matrix material 4B. As a result, in the blue light-emitting element 3B according to the present embodiment, the injection efficiency of electrons from the electron transport layer 34 to the inorganic matrix material 4B is reduced as compared with a case where the first auxiliary layer 36B is not provided or a case where the injection barrier described above is not provided.

In general, in a light-emitting element of an electric field injection type including quantum dots as a light-emitting material, due to high mobility of electrons with respect to holes or the like, excess electrons in which a concentration of electrons injected into the quantum dot layer is higher than a concentration of holes injected into the quantum dot layer may occur. The excess electrons in the quantum dot layer may cause an increase in deactivation process including generation of Auger electrons due to energy transfer between electrons or the like in the quantum dot layer. Thus, the excess electrons may cause a decrease in luminous efficiency of the light-emitting element, progress of deactivation of the quantum dots included in the light-emitting element, or the like.

The blue light-emitting element 3B according to the present embodiment includes the first auxiliary layer 36B, reducing the injection efficiency of electrons from the cathode 35 into the blue light-emitting layer 33B and reducing the excess electrons in the blue light-emitting layer 33B. Accordingly, the blue light-emitting element 3B according to the present embodiment improves carrier balancing in the blue light-emitting layer 33B and reduces the decrease in luminous efficiency of the blue light-emitting layer 33B or the progress of deactivation of the blue quantum dots QDB.

Additionally, as illustrated in FIG. 3, the first auxiliary layer 36B has an ionization potential higher than that of the inorganic matrix material 4B and lower than that of the electron transport layer 34. In general, a hole injection barrier from a first layer to a second layer corresponds to energy obtained by subtracting an ionization potential of the first layer from an ionization potential of the second layer. Thus, a barrier exists for each of the injection of holes from the inorganic matrix material 4B to the first auxiliary layer 36B and the injection of holes from the first auxiliary layer 36B to the electron transport layer 34.

As described above, the blue light-emitting element 3B according to the present embodiment can reduce the leakage of the holes injected into the blue light-emitting layer 33B from the inorganic matrix material 4B to the electron transport layer 34 as compared with a case where the first auxiliary layer 36B is not provided. Thus, the blue light-emitting element 3B improves a concentration of holes in the blue light-emitting layer 33B, thereby improving the carrier balancing in the blue light-emitting layer 33B and reducing the decrease in luminous efficiency of the blue light-emitting layer 33B or the progress of the deactivation of the blue quantum dots QDB.

Note that, as described above, the first auxiliary layer 36B reduces the deactivation process such as the generation of Auger electrons in the blue light-emitting layer 33B, the electron transport layer 34, and the like. Accordingly, the first auxiliary layer 36B can also reduce the occurrence of a process in which a defect may be generated in the blue light-emitting layer 33B or the electron transport layer 34, such as a process in which the Auger electrons hit the electron transport material of the blue quantum dots QDB or the electron transport layer 34. Thus, the first auxiliary layer 36B may protect the blue light-emitting layer 33B or the electron transport layer 34 and improve reliability of the blue light-emitting layer 33B or the electron transport layer 34.

Although the relationship between the band gaps of the respective portions of the blue light-emitting element 3B has been described with reference to FIG. 3, the band gaps of the respective portions of the red light-emitting element 3R and the green light-emitting element 3G may also have a relationship similar to that of the band gaps illustrated in FIG. 3. For example, also in the red light-emitting element 3R, the first auxiliary layer 36R may have a lower electron affinity and a higher ionization potential than those of the inorganic matrix material 4R and may have a lower ionization potential than that of the electron transport layer 34. Also in the green light-emitting element 3G, the first auxiliary layer 36G may have a lower electron affinity and a higher ionization potential than those of the inorganic matrix material 4G, and may have a lower ionization potential than that of the electron transport layer 34.

### Relationship Between Materials of Inorganic Matrix Material and First Auxiliary Layer

The first auxiliary layer 36 may contain a non-metal element contained in the inorganic matrix material 4 and a first metal element that is the same as a metal element contained in the inorganic matrix material 4. In this case, the first auxiliary layer 36 may be different from the inorganic matrix material 4 only in chemical composition while containing the same elements. In this case, the inorganic matrix material 4 and the first auxiliary layer 36 can be at least partially made of a common raw material.

In addition, the first auxiliary layer 36 may contain a non-metal element contained in the inorganic matrix material 4 and a second metal element in an upper period than that of the first metal element. In this case, the band gap of the first auxiliary layer 36 can be simply made larger than that of the inorganic matrix material 4, and the band gaps of the first auxiliary layer 36 and the inorganic matrix material 4 having the relationship illustrated in FIG. 3 can be simply achieved.

Specifically, for example, when the inorganic matrix material 4 contains ZnS, the first auxiliary layer 36 may contain Mg_{X}Zn_{1-X}S (0<X<1) or MgS. For example, when the inorganic matrix material 4 contains Mg_{X}Zn_{1-X}S (0<X<1), the first auxiliary layer 36 may contain Mg_{Y}Zn_{1-Y}S (0<X<Y<1) or MgS. For example, when the inorganic matrix material 4 contains ZnO_{1-X}S_{X} (0<X<1), the first auxiliary layer 36 may contain ZnO_{1-Y}S_{Y} (0<X<Y<1), ZnS, Mg_{Z}Zn_{1-Z}S (0<Z<1), or MgS. When the inorganic matrix material 4 and the first auxiliary layer 36 contain the above-described materials, the relationship between the band gaps of the inorganic matrix material 4 and the first auxiliary layer 36 illustrated in FIG. 3 can be achieved with a simpler configuration.

The first auxiliary layer 36 may include a mixed crystal containing the non-metal element, the first metal element, and the second metal element described above. In this case, the first auxiliary layer 36 more strongly protects the light-emitting layer 33 or the electron transport layer 34.

Note that a film thickness of the first auxiliary layer 36 may be equal to or larger than 5 nm or equal to or larger than 10 nm in order to sufficiently protect the light-emitting layer 33 and the electron transport layer 34 and to sufficiently reduce the number of holes tunneling through the first auxiliary layer 36. In addition, from the viewpoint of reducing the electrical resistance of the entire light-emitting element, the film thickness of the first auxiliary layer 36 may be equal to or less than 20 nm and may be thinner than a film thickness of the electron transport layer 34, for example.

By filling the spaces between the quantum dots with the inorganic matrix material 4, the inorganic matrix material 4 strongly protects the surfaces of the quantum dots. Thus, the display device 1 can increase the reliability of the light-emitting element included therein and suppress a decrease in luminance relative to the driving time of the light-emitting element.

### Supplements for Light-Emitting Element

The configuration of the light-emitting element 3 is not limited to the configuration illustrated in the schematic side cross-sectional view 101 of FIG. 1. For example, the light-emitting element 3 may further include a capping layer on the cathode 35 for improving light extraction efficiency from each light-emitting element. Further, the light-emitting element 3 may include a hole injection layer between each anode 31 and the hole transport layer 32.

In the present embodiment, each light-emitting element may extract light from the light-emitting layer 33 from one electrode of the anode 31 and the cathode 35 that has optical transparency. In this case, of the anode 31 and the cathode 35, the electrode on the side opposite to the electrode having optical transparency may have optical reflectivity in order to improve the extraction efficiency of light from the light-emitting layer 33.

In particular, in the present embodiment, when each light-emitting element extracts light from the light-emitting layer 33 from the electrode formed on the substrate 2 side of the anode 31 and the cathode 35, that is, the anode 31 side in the present embodiment, the substrate 2 may have optical transparency.

The light-emitting element 3 according to the present embodiment includes the anode 31 on the substrate 2 side of the anode 31 and the cathode 35 but is not limited thereto. For example, the light-emitting element 3 may include the cathode 35, the electron transport layer 34, the first auxiliary layer 36, the light-emitting layer 33, the hole transport layer 32, and the anode 31 in this order on the substrate 2. In this case, the cathode 35 may be formed in an island shape for each subpixel, or each cathode 35 may be electrically connected to the pixel circuit of the substrate 2. Further, the anode 31 may be shared by the plurality of subpixels.

### Method for Manufacturing Display Device: Up to Forming Hole Transport Layer

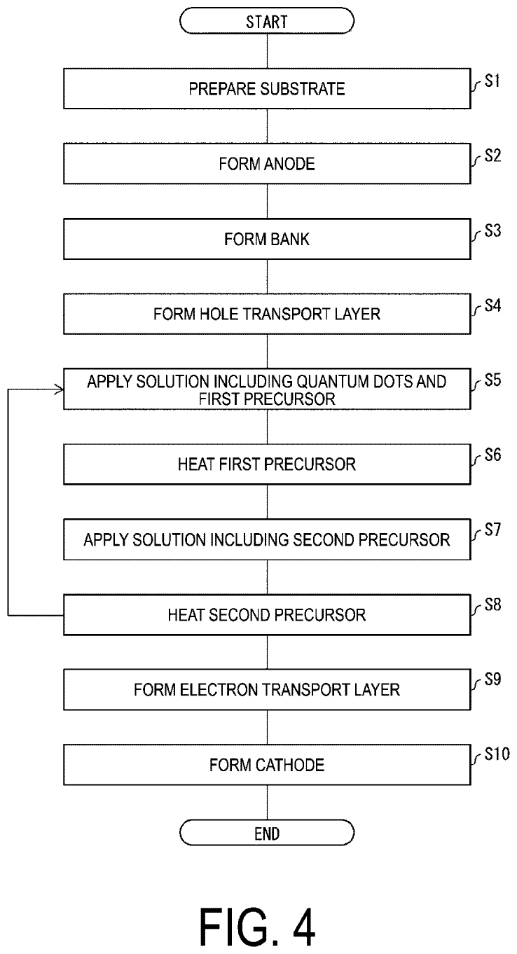

A method for manufacturing the display device 1 according to the present embodiment will be described in detail with reference to FIG. 4. FIG. 4 is a flowchart for describing the method for manufacturing the display device 1 according to the present embodiment.

With reference to FIG. 4, in the method for manufacturing the display device according to the present embodiment, first, the substrate 2 is prepared (step S1). In the present embodiment, for example, the substrate 2 including the pixel circuit for each subpixel may be manufactured by forming a thin film transistor for each subpixel on a glass substrate, a film substrate, or the like. Further, the frame portion NA may be formed by forming a driver or the like at the peripheral edge portion of the substrate 2.

Next, the anode 31 is formed on the substrate 2 (step S2). The anode 31 may be formed by, for example, forming a thin film of a metal material or the like on the substrate 2 by sputtering or the like, and then patterning the thin film by dry etching or the like.

Next, the bank BK is formed on the substrate 2 and the anode 31 (step S3). The bank BK may be formed, for example, by applying a photosensitive resin material on the substrate 2 and on the anode 31 to form a film, and then patterning the film by photolithography or the like.

Next, the hole transport layer 32 is formed on the anode 31 and on the bank BK (step S4). The hole transport layer 32 may be formed by, for example, applying a material having hole transport properties on the anode 31 and on the bank BK to form a film.

### Method for Manufacturing Display Device: Forming Light-Emitting Layer

After the completion of step S4, the process of forming the light-emitting layer 33 is performed. In forming the light-emitting layer 33, for example, first, a solution containing quantum dots and a first precursor that is a precursor of the inorganic matrix material 4 is applied onto the hole transport layer 32 formed in the subpixel corresponding to any one of the colors (step S5). In the present embodiment, the first precursor is a precursor of the first metal sulfide contained in the inorganic matrix material 4. For example, a solution in which the blue quantum dots QDB and the first precursor that is a precursor of the inorganic matrix material 4 are mixed is applied onto the hole transport layer 32 formed in the blue subpixel.

The solution may be synthesized by, for example, dispersing the quantum dots and the first precursor in a solvent such as DMF (N, N-dimethylformamide). The quantum dots may be synthesized by, for example, a known method for synthesizing quantum dots having a core/shell structure or the like. Further, in order to improve the dispersibility of the quantum dots in the solution, the solution may contain organic ligands coordinated to the outermost surfaces of the quantum dots.

The application of the solution may be implemented, for example, by using an ink-jet nozzle to discharge the solution to a position on the hole transport layer 32 overlapping with the subpixel of any one of luminescent colors and between pieces of the bank BK in a plan view of the display device 1. Thus, on the hole transport layer 32 corresponding to the subpixel of a certain luminescent color, a layer containing the quantum dots of the corresponding luminescent color and the first precursor is formed.

Next, the first precursor is heated by heating the applied solution (step S6). In step S6, for example, each layer on the substrate 2 including the applied solution is heated in an atmosphere at 150° C. for 30 minutes. Thus, the first precursor in the solution is modified into a first metal sulfide. Here, the first precursor is sequentially formed around the quantum dots in the solution by the heating in step S6. Accordingly, step S6 forms the inorganic matrix material 4 so as to fill the spaces formed between the plurality of quantum dots. As described above, a light-emitting layer including a plurality of quantum dots and the inorganic matrix material 4 with which the spaces between the quantum dots are filled is formed. Note that when the solution includes organic ligands, a weight ratio of the organic ligands in the light-emitting layer may be less than 5% by modifying the organic ligands into sulfides or vaporizing the organic ligands from the solution by heating in step S6.

### Method for Manufacturing Display Device: Forming First Auxiliary Layer

After forming the light-emitting layer 33, a process of forming the first auxiliary layer 36 is performed. In forming the first auxiliary layer 36, for example, first, a solution containing a second precursor that is a precursor of the first auxiliary layer 36 is applied to a position including the top of the light-emitting layer 33 formed in step S6 immediately before this step (step S7). In the present embodiment, a second precursor is a precursor that is different from the first metal sulfide contained in the inorganic matrix material 4, and that is a second metal sulfide contained in the first auxiliary layer 36. The application of the solution containing the second precursor may be performed by a known application method.

Next, the second precursor is heated by heating the applied solution (step S8). Step S8 may be performed by a method similar to the heating of the solution in step S6. This converts the second precursor in the solution into the second metal sulfide to form the first auxiliary layer 36 in contact with the light-emitting layer 33.

### Method for Manufacturing Display Device: Patterning Quantum Dot Layer and First Auxiliary Layer

Note that step S5 to step S8 are repeatedly performed for each subpixel while changing a luminescent color of the quantum dots in the solution that is to be discharged and a discharge position in step S5, and a precursor of the first auxiliary layer 36 that is to be discharged and a discharge position in step S7. Thus, the light-emitting layer 33 including the red light-emitting layer 33R, the green light-emitting layer 33G, and the blue light-emitting layer 33B, and the first auxiliary layer 36 including the first auxiliary layer 36R, the first auxiliary layer 36G, and the first auxiliary layer 36B are formed.

Note that when step S5 to step S8 are repeatedly performed, the light-emitting layer of any one of the subpixels already formed is heated in step S6 and step S8. However, since the inorganic matrix material 4 fills the spaces between the quantum dots in the light-emitting layer, the inorganic matrix material 4 protects the quantum dots from heat. Thus, according to the method for manufacturing the display device 1 described above, deterioration of the quantum dots in the light-emitting layer can be reduced.

As a method for forming the light-emitting layer 33 for each subpixel, the method for applying the solution separately for each subpixel by an application method such as an ink-jet method has been described in the present embodiment, but the method for forming the light-emitting layer 33 is not limited thereto. The light-emitting layer 33 may be manufactured by, for example, patterning using a lift-off method or the like.

For example, after forming a photosensitive resin layer having an opening only at a position corresponding to a certain subpixel by photolithography or the like, the solution is commonly applied over a plurality of subpixels. Thereafter, the photosensitive resin layer is removed by an appropriate developing solution, allowing the solution to be left only at the position corresponding to the certain subpixel. After that, the solution may be heated to form the light-emitting layer only at the certain subpixel.

In this case, the light-emitting layer of any subpixel that has already been formed is exposed to the developing solution when the photosensitive resin layer is peeled off. Thus, in the above-described method, each time the solution is patterned, the solution may be heated to form the light-emitting layer one by one. In this case, since the inorganic matrix material 4 fills the spaces between the quantum dots in the light-emitting layer, the inorganic matrix material 4 protects the quantum dots in the light-emitting layer that have already been formed from the developing solution. Thus, the above-described method can also reduce the deterioration of the quantum dots in the light-emitting layer.

### Method for Manufacturing Display Device: Forming Electron Transport Layer and Beyond

After forming the first auxiliary layer 36, the electron transport layer 34 is formed on the first auxiliary layer 36 (step S9). The electron transport layer 34 may be formed by applying a material having electron transport properties on the first auxiliary layer 36 to form a film, for example.

Next, the cathode 35 is formed on the electron transport layer 34 and on the bank BK (step S10). The cathode 35 may be formed by forming a thin film of a metal material or the like on the electron transport layer 34 and at the bank BK by sputtering, for example. As described above, the light-emitting element 3 exemplified in the schematic side cross-sectional view 101 of FIG. 1 is formed on the substrate 2, and the manufacturing of the display device 1 is completed.

According to the method for manufacturing the display device 1 of the present embodiment, both the light-emitting layer 33 and the first auxiliary layer 36 can be formed by applying a solution and modifying a precursor in the solution. Thus, according to the method for manufacturing the display device 1 according to the present embodiment, the light-emitting layer 33 and the first auxiliary layer 36 can be formed more simply.

Furthermore, according to the method for manufacturing the display device 1 according to the present embodiment, the electron transport layer 34 is formed on the first auxiliary layer 36. Thus, according to the method for manufacturing the display device 1 according to the present embodiment, contact of the light-emitting layer 33 with the electron transport layer 34 can be reduced, and deterioration of the quantum dots in the light-emitting layer 33 can be reduced in forming the electron transport layer 34.

### Second Embodiment

### Second Auxiliary Layer

Another embodiment of the disclosure will be described below. Further, members having the same functions as those of the members described in the above-described embodiments will be denoted by the same reference numerals and signs, and the description thereof will not be repeated for the sake of convenience of description.

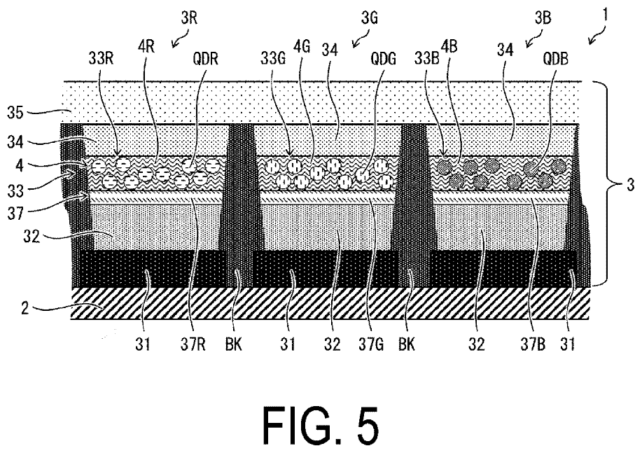

FIG. 5 is a schematic side cross-sectional view of a display device 1 according to the present embodiment. The display device 1 according to the present embodiment has the same configuration as that of the display device 1 according to the previous embodiment except that the light-emitting element 3 includes a second auxiliary layer 37 instead of the first auxiliary layer 36.

In each light-emitting element, the second auxiliary layer 37 is positioned between the anode 31 and the light-emitting layer 33, and in particular, is in contact with the light-emitting layer 33 on the anode 31 side. The second auxiliary layer 37 may be made of the same material as the inorganic matrix material, but is desirably made of a different material. The second auxiliary layer 37 includes, for example, a second auxiliary layer 37R, a second auxiliary layer 37G, and a second auxiliary layer 37B that are formed at positions overlapping with the red subpixel, the green subpixel, and the blue subpixel, respectively, in a plan view of the substrate 2. The second auxiliary layer 37R, the second auxiliary layer 37G, and the second auxiliary layer 37B may contain materials different from each other or may contain the same material as each other.

In each light-emitting element according to the present embodiment, a distance between the light-emitting layer 33 and the hole transport layer 32 is increased by a film thickness of the second auxiliary layer 37, in other words, distances between the quantum dots and the hole transport layer 32 are increased. For the same reason as described in the previous embodiment, this reduces the probability of occurrence of a process that does not contribute to light emission of the quantum dots in the light-emitting layer 33. Thus, each light-emitting element according to the present embodiment includes the second auxiliary layer 37, thereby increasing the probability of occurrence of the process contributing to the light emission of the light-emitting layer 33 and improving the luminous efficiency of the light-emitting layer 33.

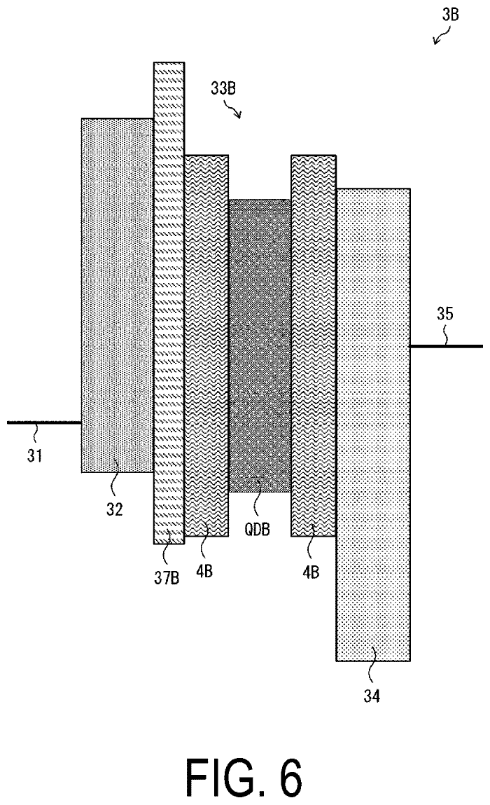

The second auxiliary layer 37 will be described in more detail by describing an example of band gaps of respective portions of the light-emitting element according to the present embodiment. FIG. 6 is a band diagram illustrating an example of the band gaps of the respective portions of the light-emitting element according to the present embodiment, in particular, the blue light-emitting element 3B.

As illustrated in FIG. 6, the second auxiliary layer 37B has an electron affinity smaller than that of the inorganic matrix material 4B and also smaller than that of the hole transport layer 32. Thus, an electron injection barrier exists from the inorganic matrix material 4B to the second auxiliary layer 37B. Furthermore, the electron injection barrier from the inorganic matrix material 4B into the second auxiliary layer 37B is larger than an injection electron barrier from the inorganic matrix material 4B into the hole transport layer 32. Thus, in the blue light-emitting element 3B according to the present embodiment, as compared with a case where the second auxiliary layer 37B is not provided or a case where the electron injection barrier described above is not provided, electrons injected into the blue light-emitting layer 33B are less likely to flow out to the hole transport layer 32 side and become a reactive current.

Additionally, an ionization potential of the second auxiliary layer 37B is equivalent to an ionization potential of the inorganic matrix material 4B. Note that in this specification, the expression “ionization potentials of two layers are equivalent to each other” does not necessarily mean that the ionization potentials of the two layers have exactly the same value. For example, the ionization potentials of the two layers described above may have a difference equal to or less than 0.5 eV. FIG. 6 illustrates an example in which the ionization potential of the second auxiliary layer 37B is higher than the ionization potential of the inorganic matrix material 4B, but the present embodiment is not limited thereto. For example, the case where the ionization potential of the second auxiliary layer 37B is smaller than the ionization potential of the inorganic matrix material 4B, but the difference therebetween is equal to or less than 0.5 eV is also included in the present embodiment.

Thus, a hole injection barrier from the hole transport layer 32 to the second auxiliary layer 37B is not significantly different from a hole injection barrier from the hole transport layer 32 to the inorganic matrix material 4B. There is almost no hole injection barrier from the second auxiliary layer 37 into the inorganic matrix material 4B. Thus, the second auxiliary layer 37B reduces a decrease in injection efficiency of holes from the anode 31 to the blue light-emitting layer 33B. As a result, the second auxiliary layer 37B reduces deterioration in carrier balancing in the blue light-emitting layer 33B, and reduces a decrease in luminous efficiency of the blue light-emitting layer 33B or the progress of deactivation of the blue quantum dots QDB.

Like the first auxiliary layer 36, the second auxiliary layer 37B illustrated in FIG. 6 may contain the non-metal element contained in the inorganic matrix material 4B and at least one of a first metal element that is the same as the metal element contained in the inorganic matrix material 4B and a second metal element in an upper period than that of the first metal element. Specifically, for example, when the inorganic matrix material 4B contains ZnS, the second auxiliary layer 37B may contain Mg_{X}Zn_{1-X}S (0<X<1) or MgS. When the inorganic matrix material 4B contains Mg_{X}Zn_{1-X}S (0<X<1), the second auxiliary layer 37B may contain Mg_{Y}Zn_{1-Y}S (0<X<Y<1) or MgS. When the inorganic matrix material 4B contains ZnO_{1-X}S_{X} (0<X<1), the second auxiliary layer 37B may contain ZnO_{1-Y}S_{Y} (0<X<Y<1), ZnS, Mg_{Z}Zn_{1-Z}S (0<Z<1), or MgS. When the inorganic matrix material 4B and the second auxiliary layer 37B contain the above-described materials, the relationship between the band gaps of the inorganic matrix material 4B and the second auxiliary layer 37B illustrated in FIG. 6 can be achieved with a simpler configuration.

### Another Example of Second Auxiliary Layer

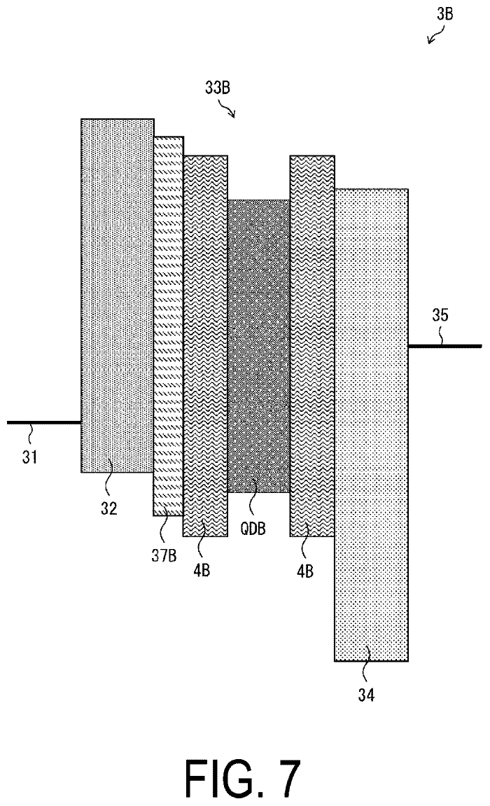

Another example of the second auxiliary layer 37 will be described in more detail by describing another example of the band gaps of respective portions of the light-emitting element according to the present embodiment. FIG. 7 is a band diagram illustrating another example of the band gaps of the respective portions of the light-emitting element according to the present embodiment, in particular, the blue light-emitting element 3B.

As illustrated in FIG. 7, the second auxiliary layer 37B has an ionization potential lower than that of the inorganic matrix material 4B and higher than that of the hole transport layer 32. In this case, a hole injection barrier from the hole transport layer 32 to the second auxiliary layer 37B and a hole injection barrier from the second auxiliary layer 37B to the inorganic matrix material 4B are both smaller than a hole injection barrier from the hole transport layer 32 to the inorganic matrix material 4B. In other words, holes from the anode 31 are more efficiently transported from the hole transport layer 32 to the inorganic matrix material 4B through the second auxiliary layer 37B than from the hole transport layer 32 to the inorganic matrix material 4B.

Thus, the second auxiliary layer 37B improves the injection efficiency of holes from the anode 31 to the blue light-emitting layer 33B. Therefore, the second auxiliary layer 37B improves carrier balancing in the blue light-emitting layer 33B and reduces a decrease in luminous efficiency of the blue light-emitting layer 33B or the progress of deactivation of the blue quantum dots QDB.

Like the second auxiliary layer 37B illustrated in FIG. 6, the second auxiliary layer 37B illustrated in FIG. 7 may also contain a non-metal element contained in the inorganic matrix material 4B and at least one of a first metal element that is the same as the metal element contained in the inorganic matrix material 4B and a second metal element in an upper period than that of the first metal element. In particular, for example, when the inorganic matrix material 4B contains Mg_{X}Zn_{1-X}S (0<X<1), the second auxiliary layer 37B may contain Mg_{Y}Zn_{1-Y}S (0<Y<X<1). When the inorganic matrix material 4B contains ZnO_{1-X}S_{X} (0<X<1), the second auxiliary layer 37B may contain ZnO_{1-Y}S_{Y} (0<X<Y<1). When the inorganic matrix material 4B and the second auxiliary layer 37B contain the above-described materials, the inorganic matrix material 4B and the second auxiliary layer 37B can achieve the relationship between the band gaps illustrated in FIG. 7 with a simpler configuration.

On the other hand, the second auxiliary layer 37B illustrated in FIG. 7 may contain an element different from the element contained in the inorganic matrix material 4B. For example, when the inorganic matrix material 4B contains ZnS, the second auxiliary layer 37B may contain CdS or In₂S₃. Also in this case, the inorganic matrix material 4B and the second auxiliary layer 37B can achieve the relationship between the band gaps illustrated in FIG. 7 with a simpler configuration.

The second auxiliary layer 37B illustrated in FIG. 6 or FIG. 7 may include a mixed crystal containing the non-metal element, the first metal element, and the second metal element described above. In this case, the second auxiliary layer 37B more strongly protects the blue light-emitting layer 33B or the hole transport layer 32.

Note that a film thickness of the second auxiliary layer 37B may be equal to or larger than 5 nm or equal to or larger than 10 nm from the viewpoint of sufficiently ensuring the functions of protecting the light-emitting layer 33 and the hole transport layer 32 and sufficiently reducing electrons tunneling through the second auxiliary layer 37B. In addition, from the viewpoint of reducing an electrical resistance of the entire light-emitting element, a film thickness of the second auxiliary layer 37B may be equal to or less than 20 nm, and may be thinner than a film thickness of the hole transport layer 32, for example.

Note that although the relationship between the band gaps of the respective portions of the blue light-emitting element 3B has been described with reference to FIG. 6 and FIG. 7, band gaps of respective portions of the red light-emitting element 3R and the green light-emitting element 3G may also have the same relationship as the band gaps illustrated in FIG. 6 or FIG. 7. Specifically, also in the red light-emitting element 3R, the second auxiliary layer 37R may have an electron affinity smaller than those of the inorganic matrix material 4R and the hole transport layer 32, and may have an ionization potential equivalent to that of the inorganic matrix material 4R. Alternatively, also in the red light-emitting element 3R, the second auxiliary layer 37R may have an ionization potential lower than that of the inorganic matrix material 4R and higher than that of the hole transport layer 32. Also in the green light-emitting element 3G, the second auxiliary layer 37G may have an electron affinity smaller than those of the inorganic matrix material 4G and the hole transport layer 32, and may have an ionization potential equivalent to that of the inorganic matrix material 4G. Alternatively, also in the green light-emitting element 3G, the second auxiliary layer 37G may have an ionization potential lower than that of the inorganic matrix material 4G and higher than that of the hole transport layer 32.

### Another Example of Method for Manufacturing Display Device

The display device 1 according to the present embodiment may be manufactured by the same method as the method for manufacturing the display device 1 according to the previous embodiment except that the order of some steps is changed and the material of the second precursor is changed.

To be more specific, in the method for manufacturing the display device 1 according to the present embodiment, step S7 and step S8 among the steps illustrated in FIG. 4 are performed after step S4. Moreover, in step S7 of the present embodiment, the second precursor is a precursor of the second metal sulfide contained in the second auxiliary layer 37. Instead, in the method for manufacturing the display device 1 according to the present embodiment, step S9 is performed after the completion of step S6. In this manner, the display device 1 according to the present embodiment and including the second auxiliary layer 37 in the light-emitting element 3 is manufactured.

Also in the method for manufacturing the display device 1 according to the present embodiment, both the light-emitting layer 33 and the second auxiliary layer 37 can be formed by applying a solution and modifying a precursor in the solution. As a result, according to the method for manufacturing the display device 1 according to the present embodiment, the light-emitting layer 33 and the second auxiliary layer 37 can be formed more simply.

### Third Embodiment

### Display Device Including Two Auxiliary Layers

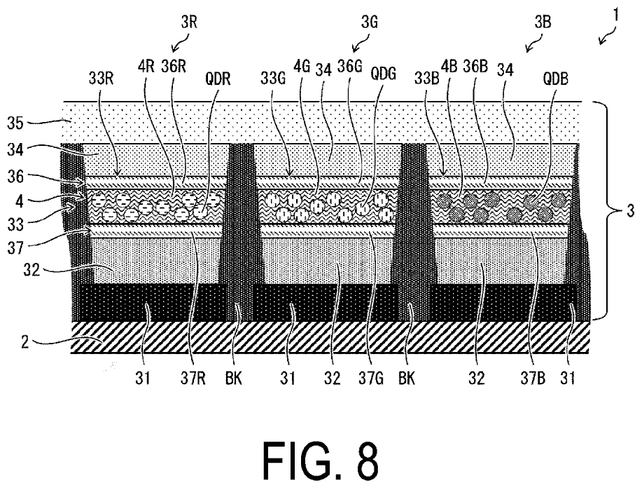

FIG. 8 is a schematic side cross-sectional view of a display device 1 according to the present embodiment. The display device 1 according to the present embodiment has the same configuration as that of the display device 1 according to each of the above-described embodiments except that the light-emitting element 3 includes both the first auxiliary layer 36 and the second auxiliary layer 37.

Also in the present embodiment, the first auxiliary layer 36 is positioned between the light-emitting layer 33 and the cathode 35 in each light-emitting element, and is, in particular, in contact with the light-emitting layer 33 on the cathode 35 side. In addition, the second auxiliary layer 37 is positioned between the anode 31 and the light-emitting layer 33 in each light-emitting element, and is, in particular, in contact with the light-emitting layer 33 on the anode 31 side. The first auxiliary layer 36 and the second auxiliary layer 37 may be made of the same material as the inorganic matrix material, but are preferably made of different materials.

In each light-emitting element according to the present embodiment, the quantum dots in the light-emitting layer 33 can be separated from both the hole transport layer 32 and the electron transport layer 34. Thus, each light-emitting element according to the present embodiment includes the first auxiliary layer 36 and the second auxiliary layer 37, thereby further increasing the probability of occurrence of the process contributing to the light emission of the light-emitting layer 33 and further improving the luminous efficiency of the light-emitting layer 33.

The first auxiliary layer 36 and the second auxiliary layer 37 according to the present embodiment may include any of the materials of the first auxiliary layer 36 and the second auxiliary layer 37 described above, respectively. Moreover, the first auxiliary layer 36 may have the band gap illustrated in FIG. 3, and the second auxiliary layer 37 may have the band gap illustrated in either FIG. 6 or FIG. 7.

In this case, the first auxiliary layer 36 and the second auxiliary layer 37 further improve carrier balancing in the light-emitting layer 33 and further improve the luminous efficiency. Further, the first auxiliary layer 36 and the second auxiliary layer 37 can protect all of the light-emitting layer 33, the hole transport layer 32, and the electron transport layer 34.

In the present embodiment, the example has been described in which each of the red light-emitting element 3R, the green light-emitting element 3G, and the blue light-emitting element 3B includes the first auxiliary layer 36 and the second auxiliary layer 37, but the configuration of the display device 1 according to the present embodiment is not limited thereto. For example, the display device 1 may include the first auxiliary layer 36 and the second auxiliary layer 37 in at least one of the red light-emitting element 3R, the green light-emitting element 3G, and the blue light-emitting element 3B. For example, the red light-emitting element 3R may include only the first auxiliary layer 36R, the green light-emitting element 3G may include both the first auxiliary layer 36G and the second auxiliary layer 37G, and the blue light-emitting element 3B may include only the second auxiliary layer 37B.

The display device 1 according to the present embodiment may be manufactured by the same method as the method for manufacturing the display device 1 according to the previous embodiment except that one or some steps are added and performed. To be more specific, in the method for manufacturing the display device 1 according to the present embodiment, step S7 and step S8 among the steps illustrated in FIG. 4 are performed after step S4. Additionally, in step S7 of the present embodiment, as in step S7 of the previous embodiment, the second precursor is a precursor of the second metal sulfide contained in the second auxiliary layer 37. Note that in the method for manufacturing the display device 1 according to the present embodiment, step S7 and subsequent steps are performed after the completion of step S6. In step S7 subsequent to step S6, the second precursor is a precursor of the first metal sulfide contained in the first auxiliary layer 36. Thereby, the display device 1 including both the first auxiliary layer 36 and the second auxiliary layer 37 according to the present embodiment in the light-emitting element 3 is manufactured.

Also, by the method for manufacturing the display device 1 according to the present embodiment, each of the first auxiliary layer 36, the light-emitting layer 33, and the second auxiliary layer 37 can be formed by applying a solution and modifying a precursor in the solution. Thus, according to the method for manufacturing the display device 1 according to the present embodiment, the first auxiliary layer 36, the light-emitting layer 33, and the second auxiliary layer 37 can be formed more simply.

The disclosure is not limited to the embodiments described above, and various modifications may be made within the scope of the claims. Embodiments obtained by appropriately combining technical approaches disclosed in the different embodiments also fall within the technical scope of the disclosure. For example, the display device 1 may include the first auxiliary layer 36 or the second auxiliary layer 37 in at least one of the red light-emitting element 3R, the green light-emitting element 3G, and the blue light-emitting element 3B. For example, the red light-emitting element 3R may include only the first auxiliary layer 36R, and each of the green light-emitting element 3G and the blue light-emitting element 3B may include neither the first auxiliary layer 36 nor the second auxiliary layer 37. Since the band gap of the light-emitting layer is the smallest in the red light-emitting element 3R, the configuration of the disclosure may effectively contribute to many cases. Furthermore, novel technical features can be formed by combining the technical approaches disclosed in each of the embodiments.

1. A light-emitting element comprising:
an anode and a cathode;
a light-emitting layer positioned between the anode and the cathode, the light-emitting layer including a plurality of quantum dots and an inorganic matrix material with which spaces between the plurality of quantum dots are filled; and
at least either
(i) an electron transport layer positioned between the light-emitting layer and the cathode and a first auxiliary layer being in contact with the light-emitting layer on a cathode side, the first auxiliary layer being made of a material different from the inorganic matrix material or
(ii) a hole transport layer positioned between the anode and the light-emitting layer and a second auxiliary layer being in contact with the light-emitting layer on an anode side, the second auxiliary layer being made of a material different from the inorganic matrix material.

2. The light-emitting element according to claim 1,
wherein a weight percentage of an organic ligand included in the light-emitting layer is less than 5%.

3-5. (canceled)

6. The light-emitting element according to claim 1,
wherein the electron transport layer and the first auxiliary layer are provided, and
the first auxiliary layer has at least one of a small electron affinity, compared with an electron affinity of the inorganic matrix material, or a small ionization potential, compared with an ionization potential of the electron transport layer.

7-8. (canceled)

9. The light-emitting element according to claim 1,
wherein the electron transport layer and the first auxiliary layer are provided, and
the first auxiliary layer includes a non-metal element included in the inorganic matrix material, and at least one of a first metal element included in the inorganic matrix material and a second metal element in an upper period than a period of the first metal element.

10. The light-emitting element according to claim 9,
wherein the first auxiliary layer includes a mixed crystal including the non-metal element, the first metal element, and the second metal element.

11. The light-emitting element according to claim 9,
wherein the inorganic matrix material includes ZnS, and
the first auxiliary layer includes Mg_{X}Zn_{1-X}S (0<X<1), or MgS.

12. The light-emitting element according to claim 9,
wherein the inorganic matrix material includes Mg_{X}Zn_{1-X}S (0<X<1), and
the first auxiliary layer includes Mg_{Y}Zn_{1-Y}S (0<X<Y<1), or MgS.

13. The light-emitting element according to claim 9,
wherein the inorganic matrix material includes ZnO_{1-X}S_{X} (0<X<1), and
the first auxiliary layer includes ZnO_{1-Y}S_{Y} (0<X<Y<1), ZnS, Mg_{Z}Zn_{1-Z}S (0<Z<1), or MgS.

14. The light-emitting element according to claim 1,
wherein the hole transport layer and the second auxiliary layer are provided, and
the second auxiliary layer includes a non-metal element included in the inorganic matrix material and at least one of a first metal element included in the inorganic matrix material and a second metal element in an upper period than a period of the first metal element.

15-17. (canceled)

18. The light-emitting element according to claim 14,
wherein the second auxiliary layer includes a mixed crystal including the non-metal element, the first metal element, and the second metal element.

19. The light-emitting element according to claim 14,
wherein the inorganic matrix material includes ZnS, and
the second auxiliary layer includes Mg_{X}Zn_{1-X}S (0<X<1), or MgS.

20. The light-emitting element according to claim 14,
wherein the inorganic matrix material includes Mg_{X}Zn_{1-X}S (0<X<1), and
the second auxiliary layer includes Mg_{Y}Zn_{1-Y}S (0<X<Y<1), or MgS.

21. The light-emitting element according to claim 14,
wherein the inorganic matrix material includes ZnO_{1-X}S_{X} (0<X<1), and
the second auxiliary layer includes ZnO_{1-Y}S_{Y} (0<X<Y<1), ZnS, Mg_{Z}Zn_{1-Z}S (0<Z<1), or MgS.

22. The light-emitting element according to claim 1,
wherein the hole transport layer and the second auxiliary layer are provided, and
the second auxiliary layer has a small ionization potential, compared with an ionization potential of the inorganic matrix material.

23. The light-emitting element according to claim 22,
wherein the second auxiliary layer has a large ionization potential, compared with an ionization potential of the hole transport layer.

24. The light-emitting element according to claim 22,
the inorganic matrix material includes ZnS, and
the second auxiliary layer includes CdS or In₂S₃.

25. The light-emitting element according to claim 22,
wherein the second auxiliary layer includes a non-metal element included in the inorganic matrix material, and at least one of a first metal element included in the inorganic matrix material and a second metal element in an upper period than a period of the first metal element.

26. The light-emitting element according to claim 25,
wherein the second auxiliary layer includes a mixed crystal including the non-metal element, the first metal element, and the second metal element.

27. The light-emitting element according to claim 25,
wherein the inorganic matrix material includes Mg_{X}Zn_{1-X}S (0<X<1), and
the second auxiliary layer includes Mg_{Y}Zn_{1-Y}S (0<Y<X<1).

28. The light-emitting element according to claim 25,
wherein the inorganic matrix material includes ZnO_{1-X}S_{X} (0<X<1), and
the second auxiliary layer includes ZnO_{1-Y}S_{Y} (0<X<Y<1).

29-33. (canceled)
